(19) United States
(12) Patent Application Publication
(10) Pub. No.: US 2020/0194506 A1
(43) Pub. Date: Jun. 18, 2020

(54) TOUCH DISPLAY APPARATUS AND METHOD FOR MANUFACTURING SAME

(71) Applicant: Wuhan China Star Optoelectronics Semiconductor Display Technology Co., Ltd., Wuhan (CN)

(72) Inventor: Bo LI, Wuhan (CN)

(73) Assignee: Wuhan China Star Optoelectronics Semiconductor Display Technology Co., Ltd., Wuhan (CN)

(21) Appl. No.: 16/462,534

(22) PCT Filed: Feb. 25, 2019
(86) PCT No.: PCT/CN2019/076190

§ 371 Date: May 21, 2019

(30) Foreign Application Priority Data
Dec. 13, 2018 (CN) 201811522191.2

(51) Int. Cl. H01L 27/32; G06F 3/044; G06F 3/041

(52) U.S. Cl. CPC H01L 27/323; G06F 3/0446; G06F 3/0443; H01L 2227/323; G06F 3/0412; H01L 2251/5338; G06F 2203/04103; H01L 27/3244

(57) ABSTRACT

A touch display apparatus is provided. The touch display apparatus includes an organic light emitting diode display panel, which includes a thin film transistor back plate, a light emitting layer, an encapsulation layer, and a substrate layer disposed on the encapsulation layer. First electrode strings disposed on the substrate layer along a first direction, each of the first electrode strings includes a plurality of first electrode units. Second electrode strings disposed on the substrate layer along a second direction and insulated from the first electrode strings, each of the second electrode strings includes a plurality of second electrode units. The first electrode strings and the second electrode strings are disposed on the same layer. A first bridging structure is electrically connected to two adjacent first electrode units or two adjacent second electrode units for increasing touch sensing areas. A method for manufacturing the touch display apparatus is also provided.

### FIELD OF INVENTION

This disclosure relates to touch display technology, and more particularly, to a touch display apparatus and a method for manufacturing the touch display apparatus.

### BACKGROUND OF INVENTION

In recent years, active matrix organic light-emitting diode (AMOLED) display technology has developed rapidly, and the corresponding touch technology has also been followed up. Currently, touch technology with active matrix organic light-emitting diode display mainly includes add-on touch film bonding technology and glass encapsulation rigid in-cell touch panel technology. In the add-on touch film bonding technology or the glass encapsulation rigid in-cell touch panel technology, there is a problem of increasing a thickness of products and affecting a narrow-frame design. As shown in FIG. 1, a display panel manufactured by the add-on touch film bonding technology includes a TFT (Thin-Film Transistor) substrate 10, an optical medium layer 11, a thin film encapsulation layer 12, an optical adhesive layer 13, a touch film layer 14, a polarizer 15, an optical adhesive layer 16, and a cover glass 17. The touch film layer 14 and the active matrix organic light emitting diode display panel are bonded together through the optical adhesive layer 13. The touch film layer 14 can be disposed above or below the polarizer 15 according to requirements. Since a number of bonding times is increased, fitting tolerances are generally greater than 0.1 mm, and use of the add-on touch film bonding technology will increase the thickness of a product and is disadvantageous to a narrow-frame design of the product.

As shown in FIG. 2, a display panel manufactured by the glass encapsulation rigid in-cell touch panel technology includes a TFT substrate 20, an optical medium layer 21, an encapsulating glass layer 22, a touch wires layer 23, a polarizer 24, an optical adhesive layer 25, and a cover glass 26. A touch sensing circuit is formed on the encapsulating glass layer 22 of the display panel, and then one side of the encapsulating glass layer 22 is bonded to an organic light-emitting diode (OLED) panel through glass glue, and there is no need to bond an add-on touch film. However, this structure is only suitable for manufacturing rigid active matrix organic light emitting diode displays, and an overall thickness of the display is thick, which is not suitable for a development direction of current products. In addition, directly forming a touch panel on the OLED panel may be interfered by signals of a lower OLED panel, and touch sensitivity is poor.

Therefore, it is necessary to provide a touch display apparatus and a manufacturing method thereof, which solve drawbacks of increasing the thickness of the product and the poor sensitivity of the touch panel in the conventional technology.

### SUMMARY OF INVENTION

In the conventional touch display, the use of the add-on touch film bonding technology will increase the thickness of a product and is not conducive to the narrow-frame design of the product. Moreover, directly forming the touch panel on the OLED panel may be interfered by signals of a lower OLED panel, and thus a touch sensing is insensitivity.

The object of this disclosure is to provide a touch display apparatus. The touch display apparatus comprises an organic light emitting diode display panel. The organic light emitting diode display panel comprises a thin film transistor back plate, a light emitting layer disposed on the thin film transistor back plate, an encapsulation layer disposed on the light emitting layer, a substrate layer disposed on the encapsulation layer, a plurality of first electrode strings disposed on the substrate layer along a first direction, and each of the plurality of first electrode strings includes a plurality of first electrode units, and a plurality of second electrode strings disposed on the substrate layer along a second direction and insulated from the plurality of first electrode strings, each of the plurality of second electrode strings includes a plurality of second electrode units. The plurality of first electrode strings and the plurality of second electrode strings are disposed on the same layer, and a first bridging structure is electrically connected to two adjacent ones of the first electrode units or two adjacent ones of the second electrode units.

When the first bridging structure is electrically connected to the two adjacent ones of the first electrode units, the second electrode unit further includes a third electrode disposed inside the second electrode unit, and the first bridging structure is electrically connected to the third electrode and the first electrode unit.

When the first bridging structure is electrically connected to the two adjacent ones of the second electrode units, the first electrode unit further includes a fourth electrode disposed inside the first electrode unit, and the first bridging structure is electrically connected to the fourth electrode and the second electrode unit.

According to an embodiment of the touch display apparatus of the disclosure, a second bridging structure is electrically connected the fourth electrode with the second electrode unit.

According to an embodiment of the touch display apparatus of the disclosure, the second electrode unit further comprises a third electrode disposed inside the second electrode unit, and a second bridging structure is electrically connected to the third electrode and the first electrode unit.

According to an embodiment of the touch display apparatus of the disclosure, the first electrode unit and the second electrode unit respectively comprise an insulating layer disposed on the first bridging structure or the second bridging structure, and a through hole disposed above the first bridging structure or the second bridging structure, and a metal layer disposed on the insulating layer, and the metal layer electrically connected to the first bridging structure or the second bridging structure through the through hole.

According to an embodiment of the touch display apparatus of the disclosure, the third electrode is disposed in an inner region of the second electrode unit, the fourth electrode is disposed in an inner region of the first electrode unit, and the first bridging structure and the second bridging structure are respectively formed by sequentially laminating a first conductive layer, an intermediate metal layer and a second conductive layer.

According to an embodiment of the touch display apparatus of the disclosure, the first electrode unit and the second electrode unit respectively comprise an insulating layer disposed on the first bridging structure or the second bridging structure, and a through hole disposed above the first bridging structure or the second bridging structure, and a metal layer disposed on the insulating layer, the metal layer electrically connected to the first bridging structure or the second bridging structure through the through hole.

According to an embodiment of the touch display apparatus of the disclosure, the third electrode is disposed in an inner region of the second electrode unit, the fourth electrode is disposed in an inner region of the first electrode unit, and the first bridging structure and the second bridging structure are respectively formed by sequentially laminating a first conductive layer, an intermediate metal layer and a second conductive layer.

According to an embodiment of the touch display apparatus of the disclosure, the organic light emitting diode display panel further includes a protective layer disposed on the substrate layer, the protective layer completely covering the plurality of first electrode strings, the plurality of second electrode strings, the first bridging structure, and the second bridging structure.

Accor ding to an embodiment of the touch display apparatus of the disclosure, the first electrode unit is a driving electrode, and the second electrode unit is a sensing electrode.

The disclosure further provides a touch display apparatus. The touch display apparatus comprises an organic light emitting diode display panel. The organic light emitting diode display panel comprises a thin film transistor back plate, a light emitting layer disposed on the thin film transistor back plate, an encapsulation layer disposed on the light emitting layer, a substrate layer disposed on the encapsulation layer, a plurality of first electrode strings disposed on the substrate layer along a first direction, and each of the plurality of first electrode strings includes a plurality of first electrode units, and a plurality of second electrode strings disposed on the substrate layer along a second direction and insulated from the plurality of first electrode strings, each of the plurality of second electrode strings includes a plurality of second electrode units. The plurality of first electrode strings and the plurality of second electrode strings are disposed on the same layer, and a first bridging structure is electrically connected to two adjacent ones of the first electrode units or two adjacent ones of the second electrode units.

According to an embodiment of the touch display apparatus of the disclosure, the first bridging structure is electrically connected to two adjacent ones of the first electrode units, the second electrode unit further includes a third electrode disposed inside the second electrode unit, the first bridging structure is electrically connected to the third electrode and the first electrode unit, the first electrode unit further includes a fourth electrode disposed inside the first electrode unit, and a second bridging structure is electrically connected to the fourth electrode and the second electrode unit.

According to an embodiment of the touch display apparatus of the disclosure, the first bridging structure is electrically connected to two adjacent ones of the second electrode units, the first electrode unit further includes a fourth electrode disposed inside the first electrode unit, the first bridging structure is electrically connected to the fourth electrode and the second electrode unit, the second electrode unit further includes a third electrode disposed inside the second electrode unit, and a second bridging structure is electrically connected to the third electrode and the first electrode unit.

According to an embodiment of the touch display apparatus of the disclosure, the first electrode unit and the second electrode unit respectively comprise an insulating layer disposed on the first bridging structure or the second bridging structure, and a through hole disposed above the first bridging structure or the second bridging structure, and a metal layer disposed on the insulating layer, the metal layer electrically connected to the first bridging structure or the second bridging structure through the through hole.

According to an embodiment of the touch display apparatus of the disclosure, the third electrode is disposed in an inner region of the second electrode unit, and the fourth electrode is disposed in an inner region of the first electrode unit.

According to an embodiment of the touch display apparatus of the disclosure, the first bridging structure and the second bridging structure are respectively formed by sequentially laminating a first conductive layer, an intermediate metal layer and a second conductive layer.

According to an embodiment of the touch display apparatus of the disclosure, the organic light emitting diode display panel further includes a protective layer disposed on the substrate layer, the protective layer completely covering the plurality of first electrode strings, the plurality of second electrode strings, the first bridging structure, and the second bridging structure.

Accor ding to an embodiment of the touch display apparatus of the disclosure, the first electrode unit is a driving electrode, and the second electrode unit is a sensing electrode.

The disclosure further provides a method of manufacturing a touch display apparatus. The method comprises the step of: providing an organic light emitting diode display panel, wherein the organic light emitting diode display panel comprising a thin film transistor back plate; providing a light emitting layer on the thin film transistor back plate; providing an encapsulation layer on the light emitting layer; providing a substrate layer on the encapsulation layer; providing metal mesh wires on the substrate layer, wherein the metal mesh wires are configured as a plurality of first electrode strings and a plurality of second electrode strings, wherein each of the plurality of first electrode strings includes a plurality of first electrode units, and each of the plurality of second electrode strings includes a plurality of second electrode units; and forming a first bridging structure between two adjacent ones of the first electrode units or two adjacent ones of the second electrode units.

According to an embodiment of the touch display apparatus of the disclosure, the first bridging structure is electrically connected to two adjacent ones of the second electrode units, the first electrode unit further includes a fourth electrode disposed inside the first electrode unit, the first bridging structure is electrically connected to the fourth electrode and the second electrode unit, the second electrode unit further includes a third electrode disposed inside the second electrode unit, and a second bridging structure is electrically connected to the third electrode and the first electrode unit.

According to an embodiment of the touch display apparatus of the disclosure, the first bridging structure is electrically connected to two adjacent ones of the second electrode units, the first electrode unit further includes a fourth electrode disposed inside the first electrode unit, the first bridging structure is electrically connected to the fourth electrode and the second electrode unit, the second electrode unit further includes a third electrode disposed inside the second electrode unit, and a second bridging structure is electrically connected to the third electrode and the first electrode unit.

Advantageous effects of the disclosure are as follows. The disclosure provides a touch display apparatus and a method for manufacturing the touch display apparatus. A flexible active matrix organic light emitting diode display manufactured by the in-cell touch panel technology is realized by forming metal grid touch sensing wires on a thin film encapsulation layer of the flexible active matrix organic light emitting diode display. Compared with conventional technology, a thickness of the display panel can be effectively reduced, and the use of the metal grid as the touch sensing wires can make the display panel have good bending resistance characteristics and realize flexible display touch. Furthermore, a metal grid touch structure of the disclosure can effectively reduce the number of bonding times of the touch display device in a manufacturing process, reduce the thickness of the display panel, and connect touch electrodes and peripheral sensing electrodes by using different bridging structures. This design effectively enhances touch sensing signals and expands touch sensing areas, thereby improving the sensitivity of the touch sensing.

### DESCRIPTION OF DRAWINGS

FIG. 1 is a side cross-sectional schematic diagram of a structure of a conventional display panel manufactured by add-on touch film bonding technology.

FIG. 2 is a side cross-sectional schematic diagram of a structure of a conventional display panel manufactured by glass encapsulation rigid in-cell touch panel technology.

FIG. 3 is a top schematic diagram of a touch panel of a touch display apparatus according to the present disclosure.

FIG. 4 is a side cross-sectional schematic diagram of the touch display apparatus of the present disclosure.

FIG. 5 is a schematic diagram of metal grid wires of the touch display apparatus according to the present disclosure.

FIG. 6 is a schematic diagram of the touch panel of the touch display apparatus according to the present disclosure.

FIG. 7 is a structural schematic diagram of a first bridging structure of the touch display apparatus according to the present disclosure.

FIG. 8 is a structural schematic diagram of a second bridging structure of the touch display apparatus according to the present disclosure.

FIG. 9 is a flowchart of a method for manufacturing the touch display apparatus according to the present disclosure.

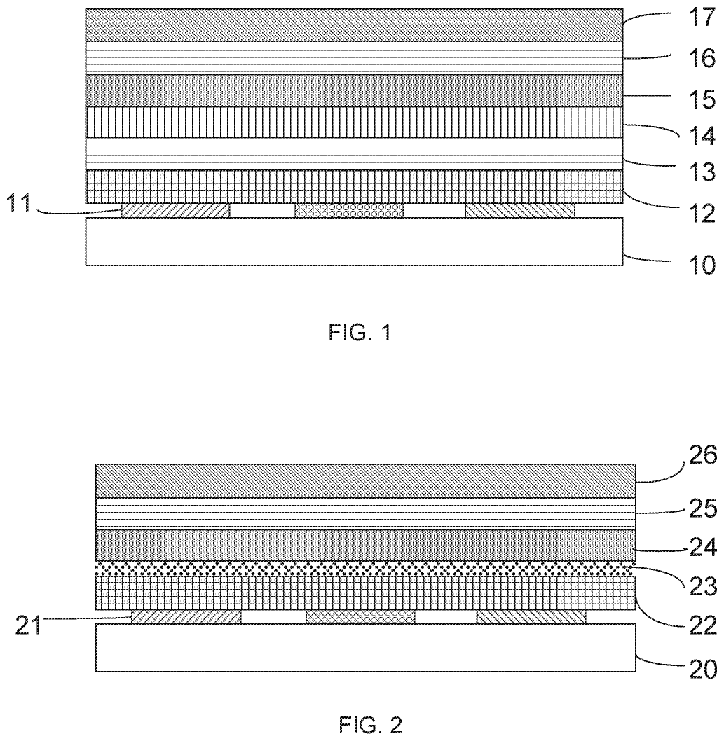

### DETAILED DESCRIPTION OF PREFERRED EMBODIMENTS

This description of the exemplary embodiments is intended to be read in connection with the accompanying drawings, which are to be considered part of the entire written description. In the description, terms such as “lower”, “upper”, “horizontal”, “vertical”, “above”, “below”, “up”, “down”, “top”, and “bottom”, as well as derivatives thereof, should be construed to refer to the orientation as then described or as shown in the drawing under discussion. These terms are for convenience of description and do not require that the apparatus be constructed or operated in a particular orientation, and do not limit the scope of the disclosure. Referring to the drawings of the disclosure, similar components are labeled with the same number.

In order to more clearly describe the embodiments of the disclosure, the description is used to make a simple introduction of the drawings used in the following embodiments.

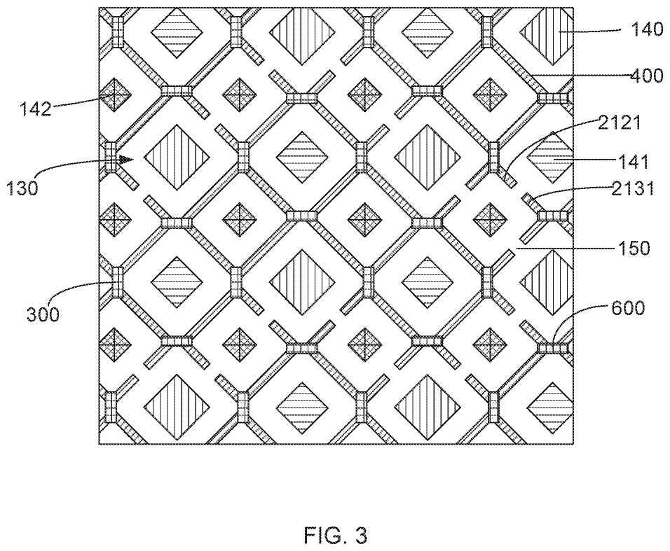

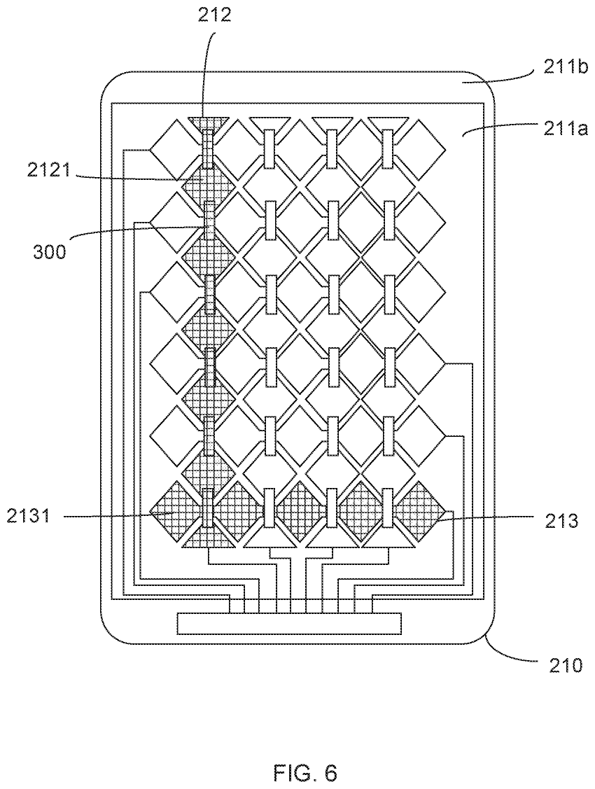

Referring to FIGS. 3-6, in which a top schematic diagram, a side cross-sectional schematic diagram of a touch panel of a touch display apparatus, and a schematic diagram of the touch panel of the touch display apparatus according to the present disclosure are shown. In an embodiment of the present disclosure, a touch display apparatus is provided. The touch display apparatus comprises an organic light emitting diode display panel 110 and a touch panel 210. The organic light emitting diode display panel 110 comprises a thin film transistor back plate 111, a light emitting layer 112 disposed on the thin film transistor back plate 111, and an encapsulation layer 113 disposed on the light emitting layer 112. The touch panel 210 comprises a substrate layer 211 disposed on the encapsulation layer 113, a plurality of first electrode strings 212 disposed on the substrate layer 211 along a first direction, each of the plurality of first electrode strings 212 includes a plurality of first electrode units 2121, and a plurality of second electrode strings 213 disposed on the substrate layer along a second direction and insulated from the plurality of first electrode strings 212, each of the plurality of second electrode strings 213 includes a plurality of second electrode units 2131. The plurality of first electrode strings 212 are interlaced with the plurality of second electrode strings 213. The plurality of first electrode strings 212 and the plurality of second electrode strings 213 are disposed on the same layer. A first bridging structure 300 is electrically connected to two adjacent ones of the first electrode units 2121 or two adjacent ones of the second electrode units 2131. In the embodiment of FIG. 6, the first bridging structure 300 is electrically connected to the adjacent first electrode units 2121. Further, in the embodiment of FIG. 6, the first direction is a horizontal direction and the second direction is a vertical direction, but is not limited thereto.

The substrate layer 211 of the touch panel 210 comprises a display area 211a and a non-display area 211b. The touch panel 210 includes a plurality of electrode regions. The electrode regions are divided into a plurality of first electrode strings 212 arranged in an array in the display area 211a, and a plurality of second electrode strings 213 disposed around the plurality of first electrode strings 212 arranged in an array. The plurality of first electrode strings 212 and the plurality of second electrode strings 213 have the same shape and area, but the shape or area of floating electrodes or virtual electrodes (will be described later) disposed in the first electrode string 212 and the second electrode string 213 are not the same.

In some embodiments, the first electrode unit 2121 is a driving electrode, and the second electrode unit 2131 is a sensing electrode. In other embodiments, the first electrode unit 2121 is a sensing electrode, and the second electrode unit 2131 is a driving electrode. Material of the first electrode unit 2121 and the second electrode unit 2131 include a transparent conductive material, such as indium tin oxide (ITO), indium zinc oxide (IZO), fluorine doped tin oxide (FTO), aluminum doped zinc oxide (AZO), gallium doped zinc oxide (GZO), or other light-transmitting conductive materials, such as a metal mesh, and a silver nano-wire (SNW), etc.

Referring to FIG. 3, touch sensing wires of the plurality of first electrode strings 212 and the plurality of second electrode strings 213 are formed by metal-mesh metal grid technology, and a plurality of metal mesh wires 400 constituting the touch sensing wires are not disposed in a pixel emitting region 130 of the organic light emitting diode display panel 110 and traces are arranged in an intermediate portion of adjacent pixels 140, 141, and 142 (e.g., pixels of different color lights). The plurality of first electrode units 2121 and the plurality of second electrode unit 2131 are formed in the same layer, and the plurality of first electrode units 2121 and the plurality of second electrode units 2131 are separated by openings 150 generated by the metal-mesh metal grid technology. A distance between two ones of the openings 150 is not greater than a distance between two adjacent pixel emitting regions. One of the plurality of first electrode units 2121 and the plurality of second electrode units 2131 are connected by a bridging structure, which will be described in detail later.

The plurality of first electrode strings 212 and the plurality of second electrode strings 213 are spatially isolated from each other.

Specifically, the second electrode unit 2131 comprises a third electrode 2133 disposed inside the second electrode unit 2131. In this embodiment, there is a gap between the second electrode unit and the third electrode, that is, the second electrode unit 2131 and the third electrode 2133 are not electrically connected to each other. A capacitance value is effectively controlled, and other noise capacitors can be shielded. The first electrode unit 2121 comprises a fourth electrode 2123 disposed inside the first electrode unit 2121. There is a gap between the first electrode unit 2121 and the fourth electrode 2123, and the first electrode unit 2121 and the fourth electrode 2123 are not electrically connected to each other. In the present embodiment, the third electrode 2133 and the fourth electrode 2123 are disposed inside the first electrode unit 2121 and the second electrode unit 2131, respectively.

In an embodiment of the present disclosure, when the first bridging structure 300 is electrically connected to two adjacent ones of the first electrode units 2121, the second electrode unit 2131 further includes a third electrode 2133 disposed inside the second electrode unit 2131 (such as the aforementioned floating electrodes or virtual electrodes). The first bridging structure 300 is electrically connected to the third electrode 2133 and the first electrode unit 2121. The first electrode unit 2121 further includes a fourth electrode 2123 (such as the aforementioned floating electrodes or virtual electrodes) disposed inside the first electrode unit 2121, and a second bridging structure 600 is electrically connected to the fourth electrode 2133 and the second electrode unit 2131.

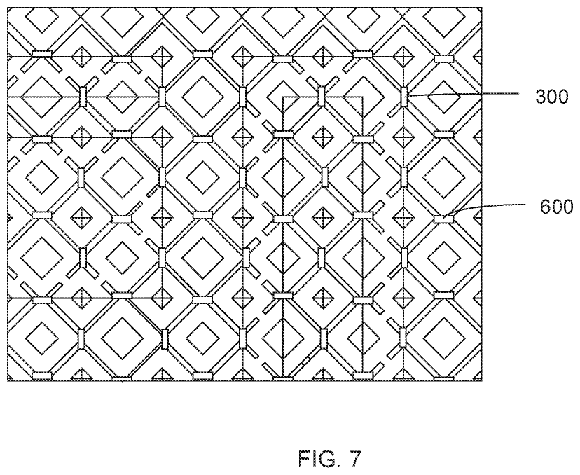

In this embodiment, the first bridging structure 300 is respectively disposed at both ends of the first electrode unit 2121. The first bridging structure 300 connects two adjacent first electrode units 2121 with each other to achieve effective communication of signals. The first bridging structure 300 conducts the third electrode 2133 inside the second electrode unit 2131 and the first electrode unit 2121 to realize the increase of a sensing area of the first electrode unit 2121 and enhance an interaction ability between a touch driving area and a sensing area. As shown in FIG. 7, two of the adjacent first electrode units 2121 isolated from each other are conducted by the plurality of zigzag-shaped first bridging structures 300, and at the same time the third electrode 2133 inside the second electrode unit 2131 is electrically conducted with the first electrode unit 2121. Thus, the sensing area of the first electrode unit 2121 and the second electrode unit 2131 is expanded to enhance the touch sensing effect.

In this embodiment, the second bridging structure 600 is disposed at an outermost periphery of the second electrode unit 2131, and the fourth electrode 2123 inside the first electrode unit 2121 is conducted with the second electrode unit 2131. The sensing area of the second electrode unit 2131 is enlarged, and the touch sensing area between the second electrode unit 2131 and the first electrode unit 2121 is increased, thereby effectively increasing the touch sensing effect and sensitivity.

In another embodiment of the present disclosure, the first bridging structure 300 is electrically connected an adjacent second electrode units 2131 instead of electrically connected an adjacent first electrode units 2121. The first electrode unit 2121 further includes a fourth electrode 2123 disposed inside the first electrode unit 2121, the first bridge structure 300 is electrically connected to the fourth electrode 2123 and the second electrode unit 2131. The second electrode unit 2131 further includes a third electrode 2133 disposed inside the second electrode unit 2131. The second bridging structure 600 is electrically connected to the third electrode 2133 and the first electrode unit 2121.

That is to say, the first bridging structure 300 is disposed at both ends of the second electrode unit 2131, that is, the first bridging structure 300 is disposed between two adjacent second electrode units 2131. The first bridging structure 300 connects two adjacent second electrode units 2131 with each other to achieve effective communication of signals. The first bridging structure 300 conducts the fourth electrode 2123 with the second electrode unit 2131 disposed inside the first electrode unit 2121 to realize an increase of the sensing area of the second electrode unit 2131, and enhance an interaction ability between the touch driving area and the sensing area.

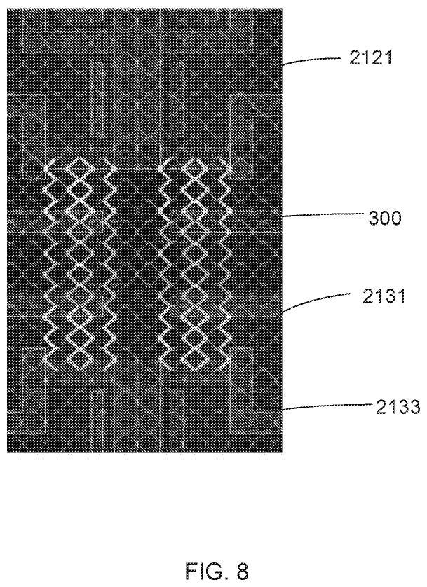

In this embodiment, the second bridging structure 600 is disposed at the outermost periphery of the first electrode unit 2121. The third electrode 2133 inside the second electrode unit 2131 is conducted with the first electrode unit 2121. The sensing area of the first electrode unit 2121 is enlarged, and a touch sensing area between the first electrode unit 2121 and the second electrode unit 2131 is increased, thereby effectively increasing touch sensing effect and sensitivity, as shown in FIG. 8.

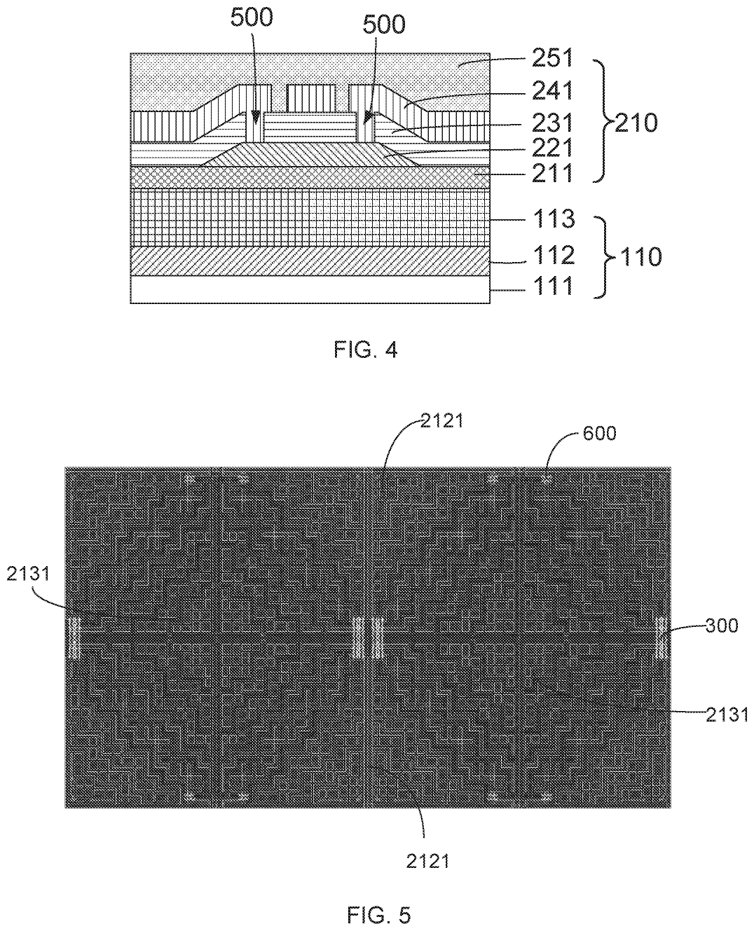

As shown in FIG. 4, the substrate layer is disposed on the encapsulation layer 113. The substrate layer 211 is preferably made of silicon nitride, but is not limited thereto. An electrode metal layer (not shown) in a form of a metal mesh wire 400 is formed on the substrate layer 211. The electrode metal layer includes a plurality of first electrode strings 212 and a plurality of second electrode strings 213. More specifically, a first metal layer 221 is disposed on the encapsulation layer 113, and the first metal layer 221 acts as the first bridging structure 300. In addition, an insulating layer 231 is disposed on the first bridging structure 300, and a through hole 500 is disposed on the insulating layer 231 corresponding to the first bridging structure 300. A second metal layer 241 is disposed on the insulating layer 231. The second metal layer 241 is electrically connected to the first bridging structure 300 through the through hole 500. The second metal layer 241 is configured to include a touch electrode pattern of the first electrode unit 2121 and the second electrode unit 2131, that is, to form metal mesh wires 400. The first bridging structure 300 conducts the first electrode unit 2121 and the second electrode unit 2131 which are isolated from each other through the through hole 500 in the insulating layer 231, thereby realizing a mutual capacitance sensing function, as shown in FIG. 4. The touch panel further includes a protective layer 251 disposed on the substrate layer 211 to completely cover the plurality of first electrode strings 212, the plurality of second electrode strings 213, the first bridge structure 300, and the second bridge structure 600.

The first bridging structure 300 and the second bridging structure 600 are respectively formed by sequentially laminating of a first conductive layer, an intermediate metal layer, and a second conductive layer. More specifically, the metal of the first bridging structure 300 and the second bridging structure 600 is formed by sequentially laminating of metals such as titanium-aluminum-titanium or molybdenum-aluminum-molybdenum. The second metal layer constituting the metal mesh wires 400 is formed by a titanium-aluminum-titanium three-layered composite metal structure, which can prevent metal oxidation and enhance the folding resistance of touch sensing wires. Preferably, the metal mesh wires 400 have a line width in a range of 0.5 microns to 5 microns.

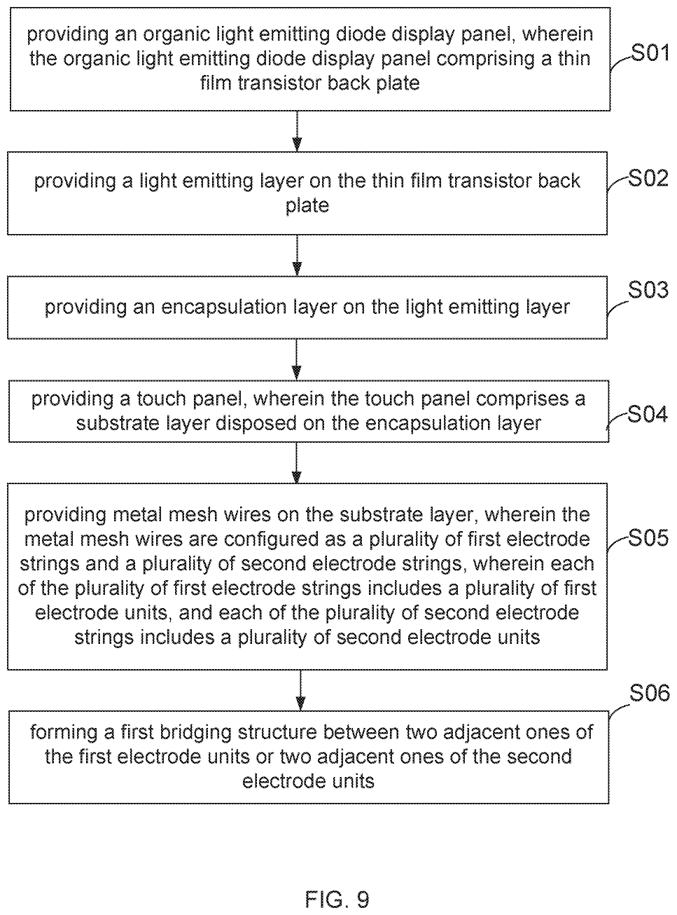

Referring to FIG. 9 accompanying with FIG. 4, a flowchart of a method for manufacturing the touch display apparatus according to the present disclosure is shown. The disclosure further provides a method of manufacturing a touch display apparatus. The method comprises following steps. In a step S01, an organic light emitting diode display panel is provided. The organic light emitting diode display panel 110 comprising a thin film transistor back plate 111. In a step S02, a light emitting layer 112 is provided on the thin film transistor back plate 111. In a step S03, an encapsulation layer is provided on the light emitting layer. In a step S04, a touch panel 210 is provided. The touch panel 210 comprises a substrate layer 211 disposed on the encapsulation layer 113. In a step S05, metal mesh wires 400 are provided on the substrate layer 211. The metal mesh wires 400 are configured as a plurality of first electrode strings 212 and a plurality of second electrode strings 213. Each of the plurality of first electrode strings 212 includes a plurality of first electrode units 2121, and each of the plurality of second electrode strings 213 includes a plurality of second electrode units 2131. In a step S06, a first bridging structure 300 is formed between two adjacent ones of the first electrode units 2121 or two adjacent ones of the second electrode units 2131.

In some embodiments, the first electrode unit 2121 is a driving electrode, and the second electrode unit 2131 is a sensing electrode. In other embodiments, the first electrode unit 2121 is a sensing electrode, and the second electrode unit 2131 is a driving electrode. Material of the first electrode unit 2121 and the second electrode unit 2131 include a transparent conductive material, such as indium tin oxide (ITO), indium zinc oxide (IZO), fluorine doped tin oxide (FTO), aluminum doped zinc oxide (AZO), gallium doped zinc oxide (GZO), or other light-transmitting conductive materials, such as a metal mesh, and a silver nano-wire (SNW), etc.

Specifically, the metal mesh wires 400 are formed by a metal-mesh metal grid technology. The metal mesh wires 400 are not disposed in a pixel emitting region of the organic light emitting diode display panel 110 and traces of the metal mesh wires are arranged in an intermediate portion of adjacent pixels. The metal mesh wires 400 have a line width in a range of 0.5 microns to 5 microns. Specifically, the substrate layer 211 is formed on the encapsulation layer 113. The substrate layer 211 is preferably made of a silicon nitride material, and then a first metal layer is formed on the substrate layer 211 as a bridging structure 300. An insulating layer 231 is formed on the first bridging structure 300, and a plurality of through holes 500 are formed above the first bridging structure 300 by an etching process. Then a second metal layer 241 is formed on the insulating layer 231. The second metal layer 241 is etched to form a touch electrode pattern including the first electrode unit 2121 and the second electrode unit 2131. The first bridging structure 300 conducts the first electrode unit 2121 and the second electrode unit 2131 which are isolated from each other through the through hole 500 in the insulating layer 231, thereby realizing a mutual capacitance sensing function.

Additionally, the second bridging structure 600 is disposed at the outermost periphery of the first electrode unit 2121 or the second electrode unit 2131. When the first bridging structure 300 is electrically connected to two adjacent ones of the first electrode units 2121, the second electrode unit 2131 further includes a third electrode 2133 disposed inside the second electrode unit 2131 (such as the aforementioned floating electrodes or virtual electrodes). The first bridging structure 300 is electrically connected to the third electrode 2133 and the first electrode unit 2121. The first electrode unit 2121 further includes a fourth electrode 2123 (such as the aforementioned floating electrodes or virtual electrodes) disposed inside the first electrode unit 2121, and the second bridging structure 600 is electrically connected to the fourth electrode 2133 and the second electrode unit 2131.

In this embodiment, the second bridging structure 600 is disposed at the outermost periphery of the second electrode unit 2131, and the fourth electrode 2123 inside the first electrode unit 2121 is conducted with the second electrode unit 2131. The sensing area of the second electrode unit 2131 is enlarged, and the touch sensing area between the second electrode unit 2131 and the first electrode unit 2121 is increased, thereby effectively increasing the touch sensing effect and sensitivity.

In another embodiment of the present disclosure, when the first bridging structure 300 is electrically connected to two adjacent ones of the second electrode units 2131, the first electrode unit 2121 further includes a fourth electrode 2123 disposed inside the first electrode unit 2121. The first bridging structure 300 is electrically connected to the fourth electrode 2123 and the second electrode units 2131. The second electrode units 2131 further includes a third electrode 2133 disposed inside the second electrode units 2131, and a second bridging structure 600 is electrically connected to the third electrode 2133 and the first electrode unit 2121.

That is to say, the first bridging structure 300 is disposed at both ends of the second electrode unit 2131, that is, the first bridging structure 300 is disposed between two adjacent second electrode units 2131. The first bridging structure 300 connects two adjacent second electrode units 2131 with each other to achieve effective communication of signals. The first bridging structure 300 conducts the fourth electrode 2123 with the second electrode unit 2131 disposed inside the first electrode unit 2121 to realize the increase of the sensing area of the second electrode unit 2131, and enhance an interaction ability between the touch driving area and the sensing area.

In this embodiment, the second bridging structure 600 is disposed at the outermost periphery of the first electrode unit 2121. The third electrode 2133 inside the second electrode unit 2131 is conducted with the first electrode unit 2121. The sensing area of the first electrode unit 2121 is enlarged, and a touch sensing area between the first electrode unit 2121 and the second electrode unit 2131 is increased, thereby effectively increasing touch sensing effect and sensitivity.

The fourth electrode 2123 (floating electrodes/virtual electrodes) disposed inside the first electrode unit 2121 is electrically conducted with the second electrode unit 2131. Alternatively, the third electrode 2133 (floating electrodes/virtual electrodes) disposed inside the second electrode unit 2131 is conducted with the first electrode unit 2121, so that the touch sensing area of the first electrode unit 2121 and the second electrode unit 2131 can be enlarged, and the touch sensing area of the first electrode unit 2121 and the second electrode unit 2131 effectively increase, thereby effectively increasing the touch sensing signal.

The disclosure provides a touch display apparatus and a method for manufacturing the touch display apparatus. A flexible active matrix organic light emitting diode display manufactured by the in-cell touch panel technology is realized by forming metal grid touch sensing wires on a thin film encapsulation layer of the flexible active matrix organic light emitting diode display. Compared with conventional technology, a thickness of the display panel can be effectively reduced, and use of the metal grid as the touch sensing wires can make the display panel have good bending resistance characteristics and realize flexible display touch. Furthermore, a metal grid touch structure of the disclosure can effectively reduce the number of bonding times of the touch display device in a manufacturing process, reduce the thickness of the display panel, and connect touch electrodes and peripheral sensing electrodes by using different bridging structures. This design effectively enhances touch sensing signals and expands touch sensing areas, thereby improving the sensitivity of the touch sensing.

This disclosure has been described with preferred embodiments thereof, and it is understood that many changes and modifications to the described embodiment can be carried out without departing from the scope and the spirit of the invention.

What is claimed is:

1. A touch display apparatus, comprising:
an organic light emitting diode display panel, the organic light emitting diode display panel comprising:
a thin film transistor back plate;
a light emitting layer disposed on the thin film transistor back plate;
an encapsulation layer disposed on the light emitting layer;
a substrate layer disposed on the encapsulation layer;
a plurality of first electrode strings disposed on the substrate layer along a first direction, wherein each of the plurality of first electrode strings includes a plurality of first electrode units; and
a plurality of second electrode strings disposed on the substrate layer along a second direction and insulated from the plurality of first electrode strings, wherein each of the plurality of second electrode strings includes a plurality of second electrode units;
wherein the plurality of first electrode strings and the plurality of second electrode strings are disposed on the same layer, and a first bridging structure is electrically connected to two adjacent ones of the first electrode units or two adjacent ones of the second electrode units;
wherein when the first bridging structure is electrically connected to the two adjacent ones of the first electrode units, the second electrode unit further includes a third electrode disposed inside the second electrode unit, and the first bridging structure is electrically connected to the third electrode and the first electrode unit;
wherein when the first bridging structure is electrically connected to the two adjacent ones of the second electrode units, the first electrode unit further includes a fourth electrode disposed inside the first electrode unit, and the first bridging structure is electrically connected to the fourth electrode and the second electrode unit.

2. The touch display apparatus according to claim 1, wherein and a second bridging structure is electrically connected the fourth electrode with the second electrode unit.

3. The touch display apparatus according to claim 1, wherein the second electrode unit further comprises a third electrode disposed inside the second electrode unit, and a second bridging structure is electrically connected to the third electrode and the first electrode unit.

4. The touch display apparatus according to claim 2, wherein the first electrode unit and the second electrode unit respectively comprise:
an insulating layer disposed on the first bridging structure or the second bridging structure, and a through hole disposed above the first bridging structure or the second bridging structure; and
a metal layer disposed on the insulating layer, and the metal layer electrically connected to the first bridging structure or the second bridging structure through the through hole.

5. The touch display apparatus according to claim 2, wherein the third electrode is disposed in an inner region of the second electrode unit, the fourth electrode is disposed in an inner region of the first electrode unit, and the first bridging structure and the second bridging structure are respectively formed by sequentially laminating a first conductive layer, an intermediate metal layer, and a second conductive layer.

6. The touch display apparatus according to claim 3, wherein the first electrode unit and the second electrode unit respectively comprise:
an insulating layer disposed on the first bridging structure or the second bridging structure, and a through hole disposed above the first bridging structure or the second bridging structure; and
a metal layer disposed on the insulating layer, the metal layer electrically connected to the first bridging structure or the second bridging structure through the through hole.

7. The touch display apparatus according to claim 3, wherein the third electrode is disposed in an inner region of the second electrode unit, the fourth electrode is disposed in an inner region of the first electrode unit, and the first bridging structure and the second bridging structure are respectively formed by sequentially laminating a first conductive layer, an intermediate metal layer, and a second conductive layer.

8. A touch display apparatus, comprising:
an organic light emitting diode display panel, the organic light emitting diode display panel comprising:
a thin film transistor back plate;
a light emitting layer disposed on the thin film transistor back plate;
an encapsulation layer disposed on the light emitting layer;
a substrate layer disposed on the encapsulation layer;
a plurality of first electrode strings disposed on the substrate layer along a first direction, wherein each of the plurality of first electrode strings includes a plurality of first electrode units; and
a plurality of second electrode strings disposed on the substrate layer along a second direction and insulated from the plurality of first electrode strings, wherein each of the plurality of second electrode strings includes a plurality of second electrode units;
wherein the plurality of first electrode strings and the plurality of second electrode strings are disposed on the same layer, and a first bridging structure is electrically connected to two adjacent ones of the first electrode units or two adjacent ones of the second electrode units.

9. The touch display apparatus according to claim 8, wherein the first bridging structure is electrically connected to two adjacent ones of the first electrode units, the second electrode unit further includes a third electrode disposed inside the second electrode unit, the first bridging structure is electrically connected to the third electrode and the first electrode unit, the first electrode unit further includes a fourth electrode disposed inside the first electrode unit, and a second bridging structure is electrically connected to the fourth electrode and the second electrode unit.

10. The touch display apparatus according to claim 8, wherein the first bridging structure is electrically connected to two adjacent ones of the second electrode units, the first electrode unit further includes a fourth electrode disposed inside the first electrode unit, the first bridging structure is electrically connected to the fourth electrode and the second electrode unit, the second electrode unit further includes a third electrode disposed inside the second electrode unit, and a second bridging structure is electrically connected to the third electrode and the first electrode unit.

11. The touch display apparatus according to claim 9, wherein the first electrode unit and the second electrode unit respectively comprise:
an insulating layer disposed on the first bridging structure or the second bridging structure, and a through hole disposed above the first bridging structure or the second bridging structure; and
a metal layer disposed on the insulating layer, the metal layer electrically connected to the first bridging structure or the second bridging structure through the through hole.

12. The touch display apparatus according to claim 9, wherein the third electrode is disposed in an inner region of the second electrode unit, and the fourth electrode is disposed in an inner region of the first electrode unit.

13. The touch display apparatus according to claim 9, wherein the first bridging structure and the second bridging structure are respectively formed by sequentially laminating a first conductive layer, an intermediate metal layer, and a second conductive layer.

14. The touch display apparatus according to claim 10, wherein the first electrode unit and the second electrode unit respectively comprise:
an insulating layer disposed on the first bridging structure or the second bridging structure, and a through hole disposed above the first bridging structure or the second bridging structure; and
a metal layer disposed on the insulating layer, the metal layer electrically connected to the first bridging structure or the second bridging structure through the through hole.

15. The touch display apparatus according to claim 10, wherein the third electrode is disposed in an inner region of the second electrode unit, and the fourth electrode is disposed in an inner region of the first electrode unit.

16. The touch display apparatus according to claim 10, wherein the first bridging structure and the second bridging structure are respectively formed by sequentially laminating a first conductive layer, an intermediate metal layer, and a second conductive layer.

17. A method of manufacturing a touch display apparatus, comprising:
providing an organic light emitting diode display panel, wherein the organic light emitting diode display panel comprising a thin film transistor back plate;
providing a light emitting layer on the thin film transistor back plate;
providing an encapsulation layer on the light emitting layer;
providing a substrate layer on the encapsulation layer;
providing metal mesh wires on the substrate layer, wherein the metal mesh wires are configured as a plurality of first electrode strings and a plurality of second electrode strings, wherein each of the plurality of first electrode strings includes a plurality of first electrode units, and each of the plurality of second electrode strings includes a plurality of second electrode units; and
forming a first bridging structure between two adjacent ones of the first electrode units or two adjacent ones of the second electrode units.

18. The method according to claim 17, wherein the first bridging structure is electrically connected to two adjacent ones of the second electrode units, the first electrode unit further includes a fourth electrode disposed inside the first electrode unit, the first bridging structure is electrically connected to the fourth electrode and the second electrode unit, the second electrode unit further includes a third electrode disposed inside the second electrode unit, and a second bridging structure is electrically connected to the third electrode and the first electrode unit.

19. The method according to claim 17, wherein the first bridging structure is electrically connected to two adjacent ones of the second electrode units, the first electrode unit further includes a fourth electrode disposed inside the first electrode unit, the first bridging structure is electrically connected to the fourth electrode and the second electrode unit, the second electrode unit further includes a third electrode disposed inside the second electrode unit, and a second bridging structure is electrically connected to the third electrode and the first electrode unit.
